(19) United States
(12) Patent Application Publication
(10) Pub. No.: US 2025/0299915 A1
(43) Pub. Date: Sep. 25, 2025

(54) IMAGE GENERATION WITH IMPROVED SCANNING LINES FOR SMART CHARGE DISTRIBUTION

(71) Applicant: Carl Zeiss SMT GmbH, Oberkochen (DE)

(72) Inventors: Daniel Schwarz, Aalen (DE); Thomas Korb, Schwäbisch Gmünd (DE)

(21) Appl. No.: 19/077,181

(22) Filed: Mar. 12, 2025

(30) Foreign Application Priority Data
Mar. 21, 2024 (DE) 102024108123.6

(51) Int. Cl. H01J 37/28; H01J 37/04

(52) U.S. Cl. CPC H01J 37/28; H01J 37/045; H01J 2237/1505; H01J 2237/2806

(57) ABSTRACT

A method of generating an image of a region of a semiconductor sample including a plurality of channels extending substantially perpendicular to a sample surface of the semiconductor sample based on a focused charged particle beam hitting a surface of the semiconductor sample along scanning lines, the method comprising at a charged particle beam imaging system the step of controlling the scanning lines of the focused charged particle beam in such a way that the scanning lines cross an interface between the semiconductor surface and each of the channels only with an angle greater or equal to 45°. The image is generated based on the scanning lines.

### CROSS-REFERENCE TO RELATED APPLICATIONS

This application claims benefit under 35 U.S.C. § 119 to German Application No. 10 2024 108 123.6, filed Mar. 21, 2024. The entire disclosure of this application is incorporated by reference herein.

### FIELD

The disclosure relates to a method of imaging a region of a semiconductor sample including a plurality of channels, and to a charged particle beam imaging system configured to generate the image.

### BACKGROUND

A semiconductor wafer can have a diameter of 300 mm and includes a plurality of several sites, so called dies, each comprising at least one integrated circuit pattern such as for example for a memory chip or for a processor chip. During fabrication, semiconductor wafers run through about 1000 process steps, and within the semiconductor wafer, about 100 and more parallel layers are formed, comprising the transistor layers, the layers of the middle of the line, and the interconnect layers and, in memory devices, a plurality of 3D arrays of memory cells. Dimensions, shapes and placements of the semiconductor structures and patterns are subject to several influences. In manufacturing of 3D-Memory devices, the processes currently include etching and deposition. Other involved process steps such as the lithography exposure or implantation also have an impact on the properties of the IC-elements.

Semiconductor structures are amongst the finest man-made structures and suffer from different imperfections. Devices for quantitative 3D-metrology, defect-detection or defect review are looking for these imperfections. Fabricated semiconductor structures are generally based on prior knowledge. The semiconductor structures are typically manufactured from a sequence of layers being parallel to a substrate. For example, in a logic type sample, metal lines run parallel in metal layers and metal vias run perpendicular to the layers. The angle between metal lines in different layers is usually either 0° or 90°. On the other hand, for 3D NAND type structures it is known that their cross-sections are circular on average.

In general, the aspect ratio and the number of layers of integrated circuits constantly increases and the structures are growing into third (vertical) dimension in order to have an increased memory capacity. The current height of the memory stacks or channels generally exceeds five microns, while in future devices this may extend to up to dozens of microns. In contrast, the features size is generally becoming smaller. The minimum feature size or critical dimension is generally below 10 nm, for example 7 nm or 5 nm, and will approach feature sizes below 3 nm in the near future, for 3D NANDS it is around 150 nm, for vertical DRAMS around 30 nm. A semiconductor layer typically has a thickness around 10 nm or less. While the complexity and dimensions of the semiconductor structures are growing into the third dimension, the lateral dimensions of integrated semiconductor structures are becoming smaller. Therefore, measuring the shape, dimensions and orientation of the features and patterns in 3D and their overlay with high precision becomes challenging.

FIG. 1 illustrates a schematic diagram of a wafer 20 with an inspection volume in the form of a 3D memory structure (a NAND-structure) of a wafer. The top and bottom portions of the structure pertain to gate logic and comprise bit lines 24, source lines 25, select gates 26, and back gates 28. Throughout the memory structure, semiconductor structures 29, 35 in the form of densely arranged HAR structures (channels) run perpendicular to the surface of the wafer. Word-lines 27 run parallel to the surface of the wafer (in x-y-direction) at specific depths.

In many cases these 3D architectures as shown in FIG. 1 include of a large number (>50) of alternating insulating and conducting layers building up to stacks of height 5-10 μm or even higher. Into these layers deep channels 29, 35 are etched which are filled with insulating and conducting material eventually. In some chip architectures such stacks are manufactured and then stacked on top of each other to get even higher memory chip capacities on the same chip area.

As shown in FIG. 2, a delicate step of the manufacturing of such structures is controlling the etch of such deep channels. Dry etch chambers 75 are designed for uni-directional etching over the full wafer using etching gas 85, but, in general, the deeper the etch the more severe slight deviations from the desired etch direction become, as shown in FIG. 2 especially in the right part showing a top view and a channel tilt distribution. For the 3D memory architectures, this often leads to unwanted channel tilts over the wafer which is often tightly controlled somehow to guarantee, e.g., the overlay of the memory cells with the underlying chip structures. The deeper the etch the more severe this issue can become.

Therefore, semiconductor manufacturers are interested in measuring this channel tilt over the wafer. With the generally increasing demands on the resolution of charged particle imaging systems in three dimensions, the inspection and 3D analysis of integrated semiconductor circuits in wafers is often becomining more and more challenging.

One way of trying to address this issue is via FIB-SEM (Focused Ion Beam-Scanning Electron Microscopy) 3D Tomography as shown in FIG. 3. Slices are cut into the structure via FIB and subsequently imaged with SEM before continuing with the next slice. Two challenges limiting this technique are charging effects and the limited throughput. Channel cross sections are typically measured on hollow channels with the SEM electron primary beam being scanned from left to right in lines from top to down while collecting secondary electrons. Since the substrate material is an insulator and the hollow channels in a multilayer are etched with SiO2 and SiN, thus isolators, the electrons often result in a local charge accumulation, the sign of which generally depends on the electron landing energy. Positive charge is typically accumulated at landing energies between a few hundred and a few thousand eV, while negative charging can occur at lower or higher beam energies. In general, positive charging will locally reduce secondary electron yield until charge is rebalanced, while negative charging will result in a deflection and deceleration of the primary beam until charge is rebalanced.

If the primary beam is scanned along an interface between a channel and the substrate, charge can accumulate at the interface and deflect subsequent scanlines, thus effectively moving edge positions in an image. FIG. 4 shows this situation for imaging a hollow channel. The first scan 1 produces positive charge along the upper channel interface. Subsequent scans 2 and 3 are influenced by this charge, which reduces the accuracy with which the channel interface may be located, and a changing contrast may make it difficult to identify the interface. This effect is mainly visible at the top edge, while the sides and bottom edges are sharp. At the bottom edge the beam is first scanned above the edge, then along the interface, so the charging effect does not reduce the accuracy of determining the channel edge position. At each slice a full image containing an array of several hundred hollow channels is acquired. The image is acquired by scanning the electron beam in lines from top to bottom as shown in FIG. 4. To accurately locate the channel edges, the pixel size with which the beam is scanned is usually rather small, on the order of 1 nm. Therefore, the beam can spend most of the time imaging the substrate which doesn't contain relevant information. For a region of interest of 10 μm by 10 μm, 1E8 pixels are imaged assuming a pixel size of 1 nm. With a dwell time per pixel of 1 μs, the acquisition of a single image takes 100 s. For 1000 slices, a full tomography run can then involve more than 27 hours in imaging time alone. Of the 1E8 pixels, only a small fraction of approximately 1% carry the relevant information of the edge location of the channels when 100 nm channel diameter and 400 channels in region of interest are assumed.

Accordingly, it would be desirable to minimize charging effects during image acquisition while accelerating the image acquisition.

### SUMMARY

According to an aspect, the disclosure provides a method of generating an image of a region of the semiconductor sample at an ion beam imaging system, wherein the sample includes a plurality of channels extending substantially perpendicular to a sample surface of the semiconductor sample and the image is generated based on a focused charged particle beam hitting the surface of the semiconductor sample along scanning lines. The method comprises the step of controlling the scanning lines of the focused charged particle beam in such a way that the scanning lines cross an interface between the semiconductor surface and each of the channels only with an angle greater or equal to 45°. The image is then generated based on the scanning lines as controlled.

The corresponding charged particle beam imaging system can be provided to generate the image of a region of the semiconductor sample operating as discussed above or as discussed in further detail below. The charged particle beam imaging system can comprise a charged particle beam generating unit configured to generate the focused charged particle beam and a control unit configured to control the focused charged particle beam along the scanning lines wherein the beam control unit is configured to control the scanning lines of focused charged particle beam in such a way that the scanning lines cross an interface between the semiconductor surface and each of the channels only with an angle greater or equal to 45°. The charged particle beam imaging system can be configured to generate the image of the region of the semiconductor sample based on a signal detected from the scanning lines.

Accordingly, instead of scanning the beam for image generation in lines from left to right and top to bottom, the beam and the scanning lines can be placed across the region to be imaged such that the charging of interfaces is minimized by avoiding scanning along channel edges.

It is to be understood that features of the disclosure mentioned above and those yet to be explained below may be used not only in the respective combinations indicated, but also in other combinations or in isolation without departing from the scope of the present disclosure.

Other features and aspects will be or will become apparent to one with skill in the art upon examination of the following detailed description when read in conjunction with the accompanying drawings in which like reference numerals refer to like elements.

### BRIEF DESCRIPTION OF THE DRAWINGS

FIG. 1 shows a schematic view of an architecture of a semiconductor sample including channel structures as known in the art.

FIG. 2 shows a schematic view of the etch gas direction distribution within an etch chamber on the left side and the resulting pattern of the channel tilt distribution over the wafer in the right side.

FIG. 3 shows a schematic new of the measurement geometry for an architecture shown in FIG. 1 as known in the art.

FIG. 4 shows a schematic view of a pattern of an electron beam scanning a channel within the architecture as shown in FIG. 1 as known in the art where unwanted charges are generated.

FIG. 5 shows a schematic view of a dual beam system with which the semiconductor structures of the wafer are examined including features of the disclosure.

FIG. 6 shows a schematic view of a scanning pattern used to avoid the situation of charging along the interface between the channel and the sample surface.

FIG. 7 shows a schematic view of a scanning pattern used to image several channels in the semiconductor structure according to the disclosure.

FIG. 8 shows a schematic view of a possible velocity distribution within the scanning lines.

FIG. 9 shows a further schematic view of a possible scanning pattern used to image an interface according to the disclosure.

FIG. 10 shows a further schematic view of a scanning pattern used to scan several channels according to the disclosure.

FIG. 11 shows a further schematic view of a possible scanning pattern used to scan several channels within the semiconductor sample according to the disclosure.

FIG. 12 shows a schematic more detailed view of the scanning pattern making sure that the scanning lines only pass from the channel to the semiconductor material.

### DETAILED DESCRIPTION

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Some examples of the present disclosure generally provide for a plurality of circuits or other electrical devices. All references to the circuits and other electrical devices and the functionality provided by each are not intended to be limited to encompassing only what is illustrated and described herein. While certain labels may be assigned to the various circuits or other electrical devices disclosed, such labels are not intended to limit the scope of operation for the circuits and the other electrical devices. Such circuits and other electrical devices may be combined with each other and/or separated in any manner based on the type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

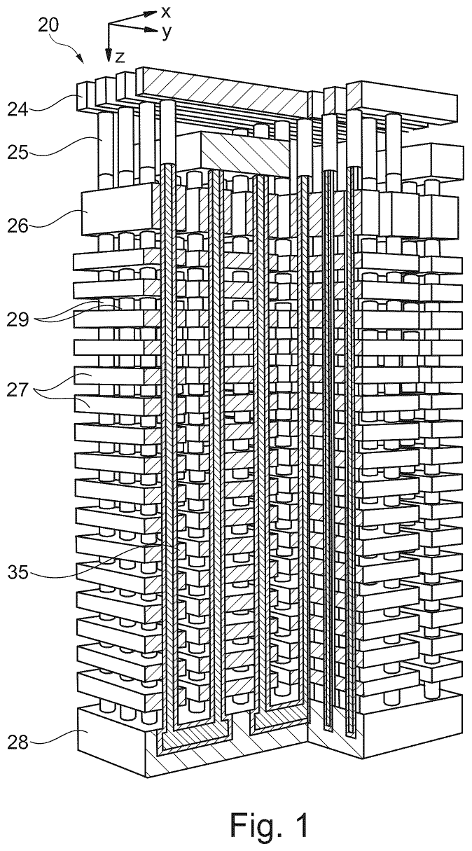

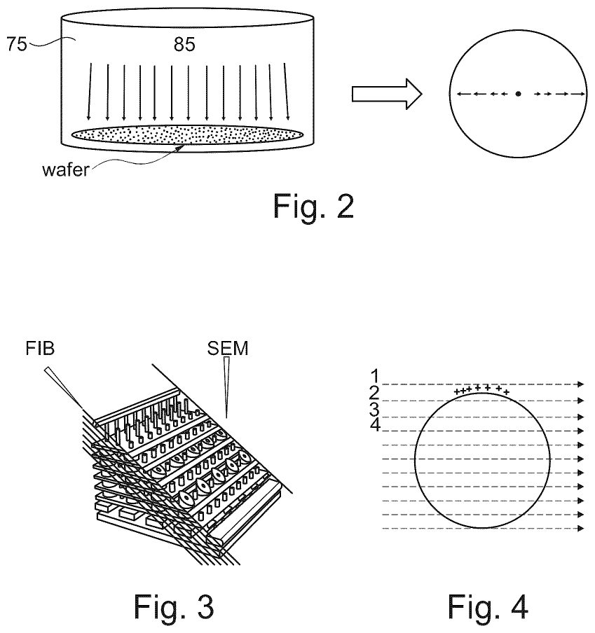

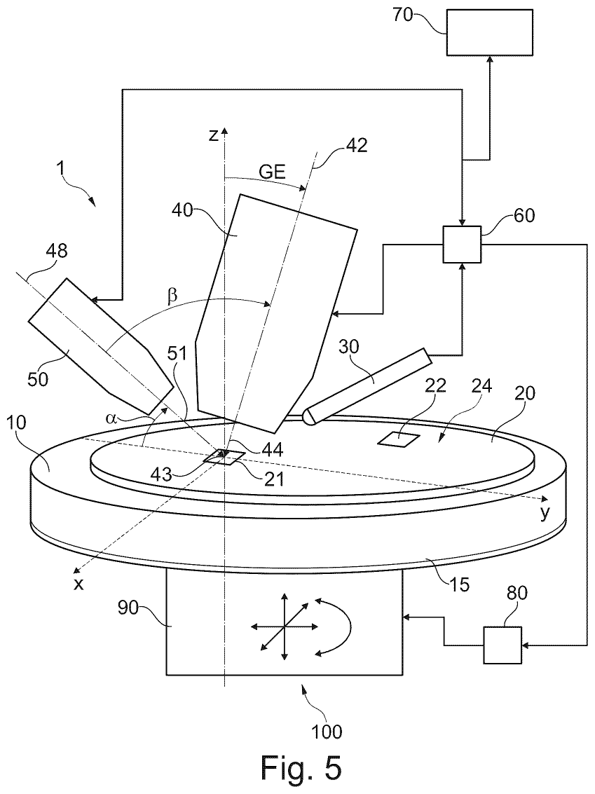

With reference to FIG. 5 a system is shown with which a structure of a semiconductor sample 20 can be examined and with which the images of the sample (a wafer) can be generated that can be used to examine channel positions. The system in FIG. 5 uses a new scanning pattern which will be explained later below. First the charged particle beam system such as an electron beam imaging system is explained in more detail. The imaging beam system 100 is configured for a slice and imaging method under wedge cut geometry with a dual beam device 1. For a wafer 20, several measurement sites, comprising measurement sites 21 and 22 are defined in a location map or inspection list generated from an inspection tool or from design information. The wafer 20 is placed on a wafer support table 10. The wafer support table 10 is mounted on a stage 90 with actuators and position control. Actuators and mechanisms for precision control for a wafer stage such as laser interferometers are known in the art. A control unit 80 is configured to control the wafer stage 90 and to adjust a measurement site 21 of the wafer 20 at the intersection point 43 of the dual-beam device 1. The dual beam device 1 comprises a FIB generating unit 50 with a FIB optical axis 48 and a charged particle beam (CPB) or scanning electron imaging system 40 with optical axis 42. It should be understood that the wedge could not only be generated by a focused ion beam, but also with the help of a laser or neutral atoms. The charged particle imaging system can generate a focused electron or ion beam 44. At the intersection point 43 of both optical axes of FIB and CPB imaging system, the wafer surface is arranged at a slant angle a to the FIB axis 48. FIB axis 48 and CPB imaging system axis 42 include an angle beta, and the CPB imaging system axis forms an angle GE with normal to the wafer surface 55. In the coordinate system of FIG. 1, the normal to the wafer surface 24 is given by the z-axis. The focused ion beam (FIB) 51 is generated by the FIB-generating unit 50 and is impinging under angle a on the surface 55 of the wafer 20. Slanted cross-section surfaces are milled into the wafer by ion beam milling at the inspection or measurement site 21 under approximately the slant or mill angle alpha (a). In the example of FIG. 5, the incidence angle alpha (a) is approximately 30°. With the charged particle beam imaging system, images of the milled surfaces can be acquired. In the example of FIG. 5, the angle GE is about 15°. However, other arrangements are possible as well, for example with GE=alpha, such that the CPB imaging system axis 42 is perpendicular to the FIB axis 48, or GE=0°, such that the CPB imaging system axis 42 is perpendicular to the wafer surface 55 as also discussed in connection with FIG. 3.

During imaging, a beam 44 of charged particles, ions such as electrons, is scanned by a scanning unit of the charged particle beam imaging system 40 along a scan path over a cross-section surface of the wafer at measurement site 21 using scanning lines, and secondary particles as well as scattered particles are generated. Particle detector 30 collects at least some of the secondary particles and scattered particles and communicates the particle count with a control unit 60, wherein the particle detector can also be provided within system 40. Other detectors for other kinds of interaction products may be present as well. The image is generated based on the scanning lines as known in the art using the back scattered and/or the secondary particles emitted from the sample based on the scanning electron beam. Control unit 60 is in control of the charged particle beam imaging system 40, of FIB generating unit 50 and connected to a further control unit 80 to control the position of the wafer mounted on the wafer support table via the wafer stage 90. Control unit 60 communicates with operation control unit 70, which triggers placement and alignment for example of measurement site 21 of the wafer 20 at the intersection point 43 via wafer stage movement and triggers repeatedly operations of FIB milling, image acquisition and stage movements. An image of the wafer surface can be generated based on particles detected when the ion beam 44, here an electron beam scans the wafer surface, wherein the image may be generated in control unit 60 or any other module of the system 100. The beam imaging system comprises a blanking system (not shown) which can quickly deflect the charged particle beam away from the surface (blank) and back (unblank). The setting time for the unblank operation can be assumed to be less than e.g. 1500 ns.

Each new intersection surface is milled by the FIB beam 51 and could be imaged by the charged particle imaging beam 44, which is for example scanning electron beam or a Helium-Ion-beam of a Helium ion microscope (HIM).

As will be explained below, in step of scanning the beam 44 in lines from left to right and top to bottom, the beam is placed across the region of interest such as the region to be imaged in such a way that first of all, the charging of interfaces is minimized by avoiding scanning along channel edges and optionally the scanning is perpendicular across the edges with the beam coming from the channel interior. Secondly, the charge will be distributed spatially and temporally to allow accumulated charge to dissipate by distributing the charging lines such that the charging lines cross the interface between channel and sample in a distributed way so that the location where the scanning lines cross the interface are evenly distributed over the interface which is substantially circular. Furthermore, as will be explained below scanning areas will be avoided that contain no relevant information. The channel can be a hollow channel or can be filled with an insulating material, and the term channel should be interpreted as to include any structure where positive or negative charge is accumulated when the structure is scanned with a charged particle beam for imaging.

In the following it might be assumed that a channel center position is known, such as from a previous slice and within a z-slice of 2 nm the center position is expected to move in a range smaller than 1 nm. Furthermore, as a further option it is possible to perform a very low dose fast pre-scan to locate the regions which carry the information, namely the locations of the channel. Furthermore, it is assumed that only a channel edge information is relevant. The control of the electron beam is available and allows to move the beam with little or no hysteresis within a few hundred nanometers. To this end an electrostatic scanner may be provided. Furthermore, the scan may be digital and freely programmable, and the beam may be speeded up or slowed down from a few tenths to hundred ns pixel dwell time. A beam blanking system is available having a setting time such as less than 1500 ns.

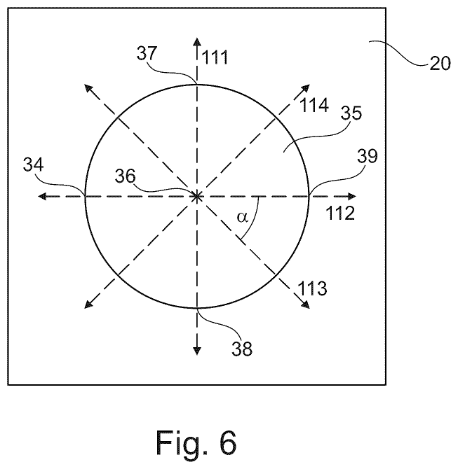

In the following a radial scan method centered in each channel is explained in more detail. As shown in FIG. 6 a channel 35 having a substantially circular shape is imaged using image pattern using different scanning lines 111 to 114. To this and the channel center position is estimated as discussed above either from a previous slice or a full image scan at the previous slice or from a top-down image or from a design file. The beam is then blanked and placed in the center 36 of the channel and unblanked. Then the beam is scanned along scan line 111 starting in the upward direction and crossing interface 37 before the scanning direction is reversed in direction of the center 36 going down and passing through the opposite interface 38. The beam may be blanked or not and the scanning direction is rotated by 90° and the scan 112 is scanned similar to the scan line 111 passing through interfaces 39 and 34. Then the scan direction is again rotated hereby 45° and again 2 perpendicular scanlines such as scanlines 113 and 114 are scanned.

With the scanning method explained in connection with FIG. 6, it can be seen that any possible charges occurring by the electron beam interfaces 37, 38 or 39 will occur in such a way that the next scanning line is placed far away from the previous interface so that the scanning beam is not influenced by any charge occurring at the previous interfaces. By way of example the charges at interface 37 will not influence the beam at interface 38 and the charges occurring at interface 38 will not influence the beam when hitting the interfaces 34 or 39.

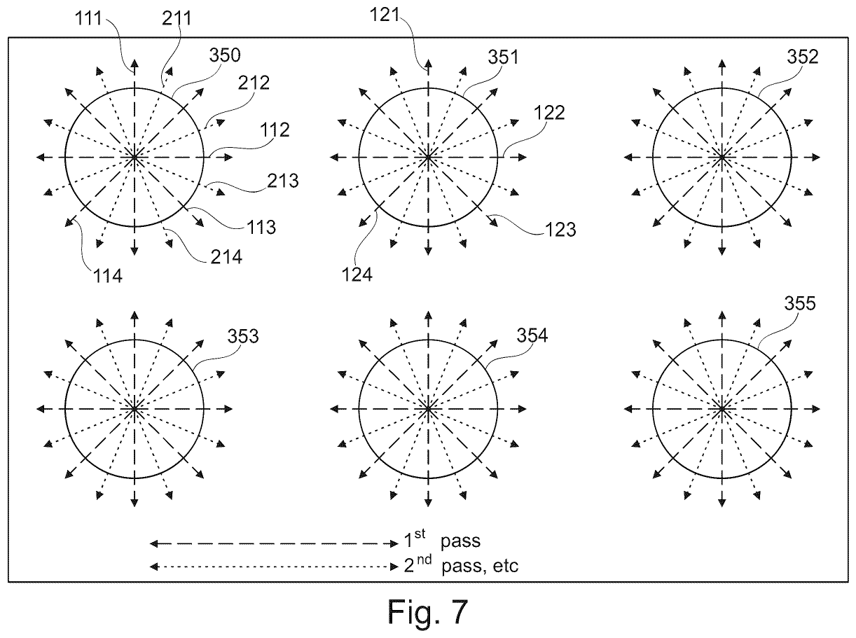

In connection with FIG. 7 a sampling and scanning scheme is explained in more detail which allows an effective generation of images of the interfaces when a distribution of channels such as channels 350 to 355 is present.

The procedure can be as follows.

Step 1: Estimate the channels center position, either from previous slice, or a full image scanned at a previous slice, or from top-down image, or from design file.

Step 2: Blank beam, place beam in center of first channel 350 and unblank.

Note: A scan rotation of r=0 means the beam is scanning along the y-axis (scan line 111), a scan rotation of r=pi/2 means the beam is scanning along the x-axis (112). With each scan two opposite edges (such as the edges 37, 38 and 34, 39 of FIG. 6) are crossed as shown in FIGS. 6 and 7.

To fully map the channel outline, one may perform scans with rotation along the semicircle from r=0 to r=pi (113), with a step size that follows from the desired precision. E.g., for a ˜1 nm spacing and a channel diameter 100 nm one may involve in total N=157 rotational scans with an angular step size of pi/N.

Subsequent scans can have linearly increasing rotation r=r+n*pi/N with n increasing linearly from 0 to N−1 before moving to the next channel. From the N rotational scans the position of the edge can be determined and the channel perimeter shape reconstructed.

However, to reduce the influence of charging on neighboring scans, it can be desirable to increase the distance of subsequent channel edge crossings. For example, an interleaved rotational scan strategy can be employed and is described here as an example. Other more complex strategies to distribute the charge along the channel perimeter are of course also possible.

In the interleaved rotational scan strategy, the N scans can be divided up into M sub-passes, where M is a divisor of N (e.g., N=160 and M=16).

Step 3. In a first subpass, the scan rotation is increased in subsequent scan passes by multiples of M.

$$r = r + n ⋆ ( M / N ) ⋆ pi$$

where n is running from 0 to N/M−1 (e.g., in the above example N=160, M=16, n=0, 1, 2, . . . , 9).

Step 4. Next, r is set to r=j*pi/N, with increasing from j=0 to M−1 (for the above example N=160, M=16, j=0, 1, 2, . . . 15). Now the next subpass (Step 1) starts, with scan rotations offset by pi/N with respect to the previous subpass.

Optionally: update channel center position for subsequent scans.

Optionally: after k subpasses, blank the beam, place beam in next channel 351, unblank and continue with step 3 to generate scanning lines 121 to 124 and more in the same fashion as for the first channel.

When all channels 350 to 355 are once measured, move to the first channel 350 again and continue with Step 3, with j=k+1 so as to generate scanning lines 211, 212, 213 and 214.

Step 5: Once all subpasses are finished, move to the next channel 350 to 355 until all channels are measured.

This method discussed in connection with FIG. 7 has the following features:
Each edge is passed perpendicular by the beam, avoiding a situation where charge is built up along the interface.
Each edge is passed by the beam coming from the vacuum side of the channel and is therefore not charged.
Only the relevant edge information is collected, which reduces imaging time.

The time for generating a full slice can be calculated as follows.

Assuming a channel diameter 100 nm and a total number of 400 individual channels are within a 10 μm region of interest. At least (314/2) radial scans for equivalent of a 1 nm pixel size along the channel perimeter are used and the scan pixel size is 1 nm with a 1 us dwell time. For each radial scan, the beam would travel approx. 300 nm (50 nm from center to first edge, plus 25 nm over edge, 75 nm back to center, 50 nm from center to second edge, plus 25 nm over edge, 75 nm back to center for next radial scan). It is possible to split the radial scans in four passes over the full set of channels to distribute charge. When switching from channel to next channel with the beam blanked, one waits the beam settling time of 1500 ns. Total measurement time is then:

$$t = 300 px \times ( \frac{314}{2} ) \times 400 \times 1 μ s + 4 \times 400 \times 1500 ns ∼ 18.8 s / layer$$

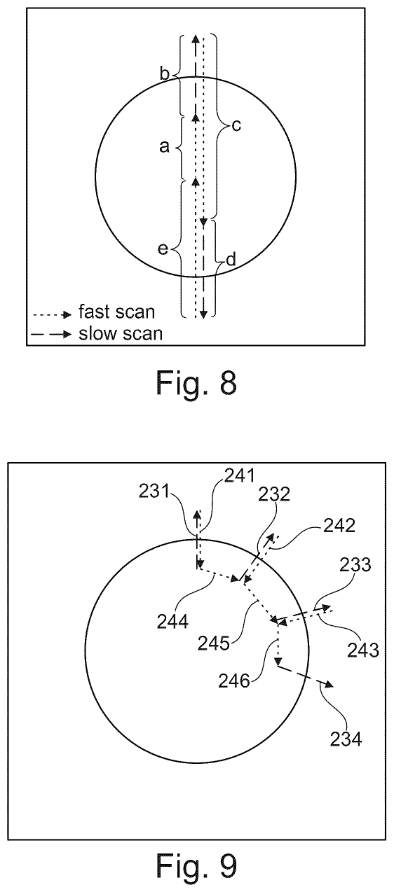

As shown in FIG. 8 further throughput improvements are possible by switching away from a constant dwell time to a scan with adaptive timing. This involves sufficient bandwidth of the scan system, which could be an electrostatic scan system with low and negligible hysteresis. However, the disclosure could also be used with a magnetic scan system. In this mode, the beam is moved fast when away from an edge, and only scanned slow, when expecting to cross a channel edge. For example, only within +/−25 nm of the expected edge position.

In FIG. 8 the beam is moved fast in section a, slow across the top edge in section b, fast towards the bottom edge in section c, slow across the bottom edge in section d and fast to the center in section e. The time for the fast scan parts is negligible (e.g., with a scan system bandwidth of 40 Mhz/25 ns per pixel, the total time for fast scan portions per scan rotation is ˜5 us or 5 extra pixels).

In this case, total time for 400 channels is:

$$t = 50 px \times \frac{314}{2} \times 400 \times 1 μ s + 4 \times 400 \times 1500 ns ∼ 3.1 s / layer$$

Another alternative is shown in FIG. 9 where the beam is scanned along the step edges still in a radial way, but only along the edges where the scan lines do not fully cover the channel width. The only slow scan line is from the hollow channel across the edge such as the scan lines 231 to 234, at all other scan lines 241 to 246 the beam moves are fast to save time and avoid charging.

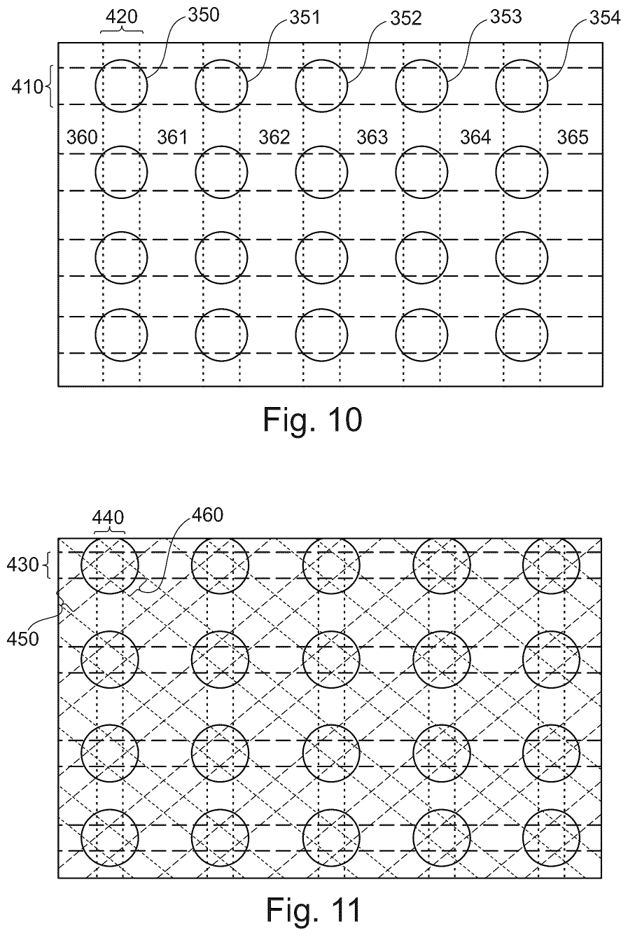

In connection with FIGS. 10 to 12 further embodiments are discussed. Here the scanning lines do not cross the interface perpendicular to the interface but still at an angle where the charging generated at the interfaces is minimized. As discussed below, the angle between the scanning lines and the interface, or to be more precise the angle between the scanning line and the tangent where the scanning line crosses the interface is still such that it is greater or equal to approximately 45°.

In FIG. 10, a charging situation at edges is avoided under glancing beam scan. In a first pass only, scan lines 410 are scanned in a line scan from left to right, the areas such as areas 360 to 365 are skipped. In a second pass, only the scan lines 420 or areas are scanned in a 90° rotated line scan from top to bottom. With both passes, full edge information about channels can be reconstructed. Accordingly, a pair of parallel scan lines is used, wherein the pair includes a first set of parallel scan lines 410 and a second set of scan lines 420. The number of scan lines is determined such that in dependence on the diameter of the channel, the scan lines at the outer border of the set 410 or 420 still crosses the interface by an angle larger or equal to 45°.

In the situation shown in FIG. 11, 2 pairs of scan lines are used. The first pair comprises the set of scan lines 430 and 440, and the second pair comprises the set of scan lines 450 and 460. It can be seen that the higher the number of pairs the smaller the number of parallel scan lines per set is. Furthermore, as the number of scan lines per set decreases the minimum angle at which the outermost scan lines of each set cross the interface increases.

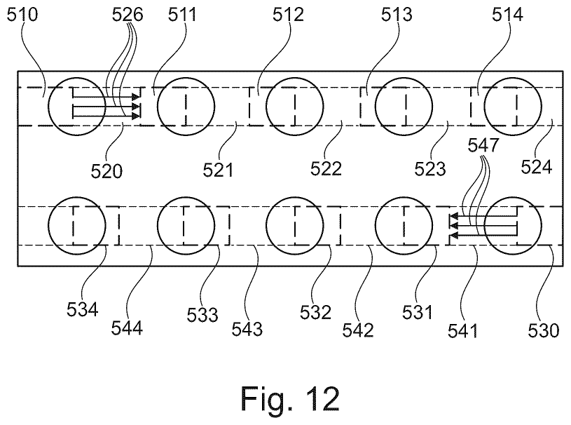

In connection with FIG. 12 a scanning scheme is discussed which ensures that each scanline to ensure that the scan passes only from hollow channel to material:

The beam is blanked when scanning from substrate towards hollow channel (accordingly in areas 510, 511, 512, 513, and 514). Then the beam is un-blanked within the channel (in areas 520 to 524), and the (right side) channel edge is scanned in areas 520 to 524 using half scanning lines 526.

Then the beam is blanked before reaching the edge of the next channel. The steps are repeated in a second pass in the reverse direction to measure the opposite (left side) channel edge by blanking the beam in areas 530 to 534 and scanning in areas 541 to 544 using half scanning lines 547. The scheme of FIG. 12 can also be combined with the schemes from FIG. 10 or 11.

From the above information, some general conclusions can be drawn.

The controlling of the scanning lines can include for each of the channels in the region the step a) of determining a position for the focused charged particle beam on the surface of the semiconductor sample inside a first channel of the plurality of channels, by way of example channel 35 or 350. Then a blanked focused charged particle beam is placed inside the first channel in step b) and in step c) an un-blanking of the focused charged particle beam is carried out. In step d) the focused charged particle beam is moved from inside the first channel along a first scanning line to the outside of the channel wherein the first scanning line extends substantially perpendicular to the interface. In step e) the charged particle beam is moved back along the first scanning line to the inside of the first channel and in step f) the focused charged particle beam is moved from the inside along the second scanning line rotated relative to the first scanning line to the outside of the first channel, wherein the second scanning line extends substantially perpendicular to the interface and in step g) the particle beam is moved back along the second scanning line back to the inside of the channel.

It is possible, to use N scanning lines for each channel, each of the N scanning lines extending substantially perpendicular to the interface, with N>100 or >200.

It is possible that for each of the scanning lines the scanning line extends over more than a channel width and each scanning line crosses two interfaces located at opposite sides of the channel as discussed above in connection with FIGS. 6 to 8, and each of the scanning line extends, at each of the 2 interfaces, substantially perpendicular to the corresponding interface. The method can then comprise the step of rotating the second scanning line directly following the first scanning line by Pi/2 relative to the first scanning line, so that scanning lines 111 and 112 are generated in FIG. 6 and a scan direction for the next scanning line is rotated.

It is possible that the scan direction is rotated by Pi/4 for the third scanning line and the fourth scanning line is rotated relative to the third scanning line by pi/2 as shown in FIG. 6 for the scanning lines 113 and 114. This leads to a uniform distribution of interfaces over the channel edge as shown in FIG. 6.

In a more general approach, the N scanning lines are rotated between r=0 and r=pi with a step size pi/N, using a rotation between subsequent scanning lines with r=r+n*pi/N, with n increasing from 0 to N−1 for the N scanning lines.

Furthermore, it is possible that in a interleaved scanning, after M scanning lines are completed for the channel, with M<N, the blanked focused charged particle beam is positioned within a next channel of the plurality of channels such as channel 351 of FIG. 7 and steps c) to g) are repeated for the next channel, wherein the scanning lines from M+1 to N for the first one of the plurality of channels are scanned after M scanning lines for the second channel are completed.

Furthermore, it is possible to have different scanning speeds within a scanning line. Each scan line can comprise a first region where the scan line has along its path an interface (e.g. the regions b) and d) in FIG. 8), and a second region where the scan line has along its path no interface (regions a, c and e in FIG. 8), wherein a dwell time is larger at the first region than at the second region.

Determining a position of the focused ion beam inside the first channel can include determining a channel center position.

As shown in FIGS. 10 to 12, each channel can be scanned with at least one pair of scanning line sets such as pairs 410, 420 of FIG. 10, wherein each pair of the scanning line sets comprises a first set of first scan lines located parallel to one another and a second set of second scan lines located parallel to one another but perpendicular to the first set of first scan lines.

As shown in FIG. 12, the first set of first scanning lines can include first half scanning lines 526 crossing a first interface of a corresponding channel from an inside of the channel to an outside of the channel and comprises second half scanning lines 547 being directed in opposite direction but parallel to the first half scanning lines and crossing a second interface of the corresponding channel from an inside of the channel to an outside of the channel.

The sample surface can comprise substrate between the plurality of channels, wherein the focused charged particle beam is blanked after the focused charged particle beam has passed from an inside of one of the channels to the substrate.

The scanning lines can be directed scanning lines such that each of the scanning line crosses the interface from an inside of one of the plurality of the channels to an outside of the corresponding channel.

As discussed above, a scanning scheme is provided which minimizes the charging of interfaces by avoiding scanning along channel edges, but optionally scans perpendicular across edges with the beam coming from the vacuum side. The charge is distributed spatially and temporally to allow accumulated charge to dissipate and scanning areas are avoided that contain no relevant information.

What is claimed is:

1. A method of generating an image of a region of a semiconductor sample, the region of the semiconductor sample comprising a plurality of channels extending substantially perpendicular to a surface of the semiconductor sample, the method comprising:
controlling scanning lines of a focused charged particle beam impinging on the surface of the semiconductor sample so that the scanning lines cross an interface between the surface of the semiconductor sample and each channel within the region of the semiconductor sample only with an angle of at least 45°; and
generating the image of the region of the semiconductor sample based on the scanning lines.

2. The method of claim 1, wherein, for each channel within the region of the semiconductor sample, controlling the scanning lines comprises:
a) determining a position of the focused charged particle beam on the surface of the semiconductor sample inside a first channel of the plurality of channels;
b) after a), placing a blanked focused charged particle beam inside the first channel;
c) after b), un-blanking the focused charged particle beam;
d) after c), moving the focused charged particle beam from inside the first channel along a first scanning line to outside of the first channel, the first scanning line extending substantially perpendicular to the interface;
e) after d), moving the ion beam back along the first scanning line to the inside the first channel;
f) after e), moving the focused ion beam from the inside the first channel along a second scanning line to outside the first channel, the second scanning line being rotated relative to the first line, the second scanning line the second scanning line extending substantially perpendicular to the interface; and
g) after f), moving the ion beam back along the second scanning line back to inside the first channel.

3. The method of claim 2, wherein N scanning lines are used for each channel, N is greater than 100, and each of the N scanning lines extends substantially perpendicular to the interface.

4. The method of claim 2, wherein for each of the N scanning lines:
the scanning line: i) extends over more than a channel width; ii) crosses two interfaces located at opposite sides of the channel; and iii) at each of the two interfaces, extends substantially perpendicular to the interface; and
the method comprises:
rotating the second scanning line directly following the first scanning line by Pi/2 relative to the first scanning line; and
rotating a scan direction for the next scanning line.

5. The method of claim 4, wherein the scan direction is rotated for the next scanning line by Pi/4 for the third scanning line, and the fourth scanning line is rotated by Pi/2 relative to the third scanning line.

6. The method of claim 3, wherein the N scanning lines are rotated between r=0 and r=pi with a step size pi/N, using a rotation between subsequent scanning lines with r=r+n*pi/N, with n increasing from 0 to N−1 for the N scanning lines for one channel.

7. The method of claim 2, wherein:
N scanning lines are used for each channel; and
in an interleaved scanning:
after completing M scanning lines for one of the plurality of channels, the blanked focused charged particle beam is positioned within a next channel of the plurality of channels and c) to g) are repeated for the next channel;
M is less than N; and
after completing M scanning lines for the next channel, scanning the scanning lines from M+1 to N for the one of the plurality of channels.

8. The method of claim 2, wherein:
each scanning line comprises: i) a first region where the scanning line has an interface along its path, and ii) a second region where the scanning line has no interface along its path; and
a dwell time is larger at the first region than at the second region.

9. The method of claim 2, wherein determining the position of the focused charged particle beam inside the first channel comprises determining a center position of the first channel.

10. The method of claim 1 wherein:
each channel is scanned with at least one pair of scanning line sets; and
each pair of scanning line sets comprises a first set of first scan lines located parallel to one another and a second set of second scan lines located parallel to one another but perpendicular to the first set of first scan lines.

11. The method of claim 10, wherein the first set of first scanning lines comprises:
first half scanning lines crossing a first interface of a corresponding channel from inside the channel to outside the channel;
second half scanning lines directed in an opposite but parallel direction to the first half scanning lines; and
the second half scanning lines cross a second interface of the corresponding channel from inside the channel to outside the channel.

12. The method of claim 1, wherein the sample surface comprises a substrate between the plurality of channels, and the focused charged particle beam is blanked after the focused ion beam passed from inside of one of the channels to the substrate.

13. The method of claim 1, wherein each of the scanning line crosses the interface from inside one of the plurality of the channels to outside the corresponding channel.

14. One or more machine-readable hardware storage devices comprising instructions that are executable by one or more processing devices to perform operations comprising the method of claim 1.

15. A system, comprising:
one or more processing devices; and
one or more machine-readable hardware storage devices comprising instructions that are executable by the one or more processing devices to perform operations comprising the method of claim 1.

16. The system of claim 15, further comprising a charged particle beam imaging system configured to generate the focused charged particle beam and generate the image.

17. A charged particle beam imaging system, comprising:
a charged particle beam generating unit comprising a charged particle beam generating unit configured to generate a focused charged particle beam configured to impinge on a semiconductor sample comprising a region which comprises a plurality of channels extending substantially perpendicular to a surface of the semiconductor sample and to generate an image of the region of the semiconductor sample; and
a controller configured to:
control the focused charged particle beam so that scanning lines of the focused charged particle beam impinge on the surface of the semiconductor sample, the scanning lines crossing an interface between the surface of the semiconductor sample and each channel within the region of the semiconductor sample only with an angle of at least 45°; and
generate the image of the region of the semiconductor sample based on a signal detected from the scanning lines.

18. The charged particle beam imaging device of claim 17, wherein the controller is configured so that, for each channel within the region of the semiconductor sample, controlling the scanning lines of the focused charged particle beam comprises:
a) determining a position of the focused charged particle beam on the surface of the semiconductor sample inside a first channel of the plurality of channels;
b) after a), placing a blanked focused charged particle beam inside the first channel;
c) after b), un-blanking the focused charged particle beam;
d) after c), moving the focused charged particle beam from inside the first channel along a first scanning line to outside of the first channel, the first scanning line extending substantially perpendicular to the interface;
e) after d), moving the ion beam back along the first scanning line to the inside the first channel;
f) after e), moving the focused ion beam from the inside the first channel along a second scanning line to outside the first channel, the second scanning line being rotated relative to the first line, the second scanning line the second scanning line extending substantially perpendicular to the interface; and
g) after f), moving the ion beam back along the second scanning line back to inside the first channel.

19. The charged particle beam imaging device of claim 18, wherein the controller is configured so that for each of the scanning lines:
the scanning line: i) extends over more than a channel width; ii) crosses two interfaces located at opposite sides of the channel; and iii) at each of the two interfaces, extends substantially perpendicular to the interface; and
controlling the scanning lines of the focused charged particle beam comprises:
rotating the second scanning line directly following the first scanning line by Pi/2 relative to the first scanning line; and
rotating a scan direction for the next scanning line.

20. The charged particle beam imaging device of claim 18, wherein:
N scanning lines are used for each channel; and
the controller is configured so that, in an interleaved scanning, controlling the scanning lines of the focused charged particle beam comprises:
after completing M scanning lines for one of the plurality of channels, the blanked focused charged particle beam is positioned within a next channel of the plurality of channels and c) to g) are repeated for the next channel;
M is less than N; and
after completing M scanning lines for the next channel, scanning the scanning lines from M+1 to N for the one of the plurality of channels.

21. The charged particle beam imaging device of claim 17, wherein:
the controller is configured to scan each channel with at least one pair of scanning line sets; and
each pair of the scanning line sets comprises a first set of first scan lines located parallel to one another and a second set of second scan lines located parallel to one another but perpendicular to the first set of first scan lines.

22. The charged particle beam imaging device of claim 17, wherein:
the sample surface comprises substrate between the plurality of channels; and
the beam controller is configured to blank the focused charged particle beam after the focused ion beam has passed from inside one of the channels to the substrate.
